(19) United States
(12) Patent Application Publication
(10) Pub. No.: US 2024/0178126 A1
(43) Pub. Date: May 30, 2024

(54) DOUBLE-SIDE COOLED POWER MODULES

(71) Applicant: VIRGINIA TECH INTELLECTUAL PROPERTIES, INC., Blacksburg, VA (US)

(72) Inventors: Guo-Quan LU, Blacksburg, VA (US); Zichen ZHANG, Blacksburg, VA (US)

(21) Appl. No.: 18/549,447

(22) PCT Filed: Mar. 14, 2022
(86) PCT No.: PCT/US2022/071120

§ 371 Date: Sep. 7, 2023

Related U.S. Application Data
(60) Provisional application No. 63/167,872, filed on Mar. 30, 2021.

(51) Int. Cl. H01L 23/498; H01L 21/48; H01L 23/00; H01L 23/373; H01L 25/00; H01L 25/07

(52) U.S. Cl. CPC H01L 23/49866; H01L 23/3735; H01L 24/29; H01L 24/32; H01L 24/33; H01L 25/072; H01L 21/4853; H01L 24/83; H01L 25/50; H01L 2224/29139; H01L 2224/32225; H01L 2224/32245; H01L 2224/33181; H01L 2224/83201; H01L 2224/8384; H01L 2924/10272; H01L 2924/1033; H01L 2924/1203; H01L 2924/20106

(57) ABSTRACT

Multi-chip module packaging technologies for GaN and other devices are described. The power module packaging technology described can be applied to all types of medium-voltage devices, such as silicon (Si), silicon carbide (SiC), gallium nitride (GaN), or the latest gallium oxide (Ga₂O₃) devices. In one example, a power module includes a first substrate, a second substrate, a sintered-silver semiconductor die pillar, the pillar being positioned between the first substrate and the second substrate, a terminal on a first side of the power module, and a terminal on a second side of the power module.

### CROSS REFERENCE TO RELATED APPLICATIONS

This application claims priority to and the benefit of U.S. Provisional Application No. 63/167,872, filed on Mar. 30, 2021, the entire contents of which is hereby incorporated herein by reference.

### GOVERNMENT LICENSE RIGHTS

This invention was made with government support under Grant No. 429408 awarded by the Advanced Research Projects Agency-Energy. This invention was also made with government support under the Advanced Research Projects Agency-Energy (ARPA-E) of the Department of Energy (DOE) under Grant No. DE-AR0001008. The United States government has certain rights in the invention.

### BACKGROUND OF THE INVENTION

With advances in medium- and high-voltage silicon carbide (SiC) devices, wide-bandgap semiconductors can be used in power grid applications. SiC power devices offer the benefits of small size, less weight, high efficiency, and other benefits for power conversion in power grids. However, the high blocking voltages of these devices place a stringent demand on electrical insulation of the packages that interconnect and insulate the devices. The constant push for higher packaging power density only exacerbates the challenge. Over the last twenty years, various module packaging approaches have been developed to improve thermal performance and increase power density. Many approaches involve replacing the conventional wire-bonded structures with sandwiched or planar structures having low package parasitic inductances. Some planar packaging approaches are already being relied upon for semiconductor devices in the sub-kV to 1.2-kV range.

### SUMMARY OF THE INVENTION

Multi-chip module packaging technologies are described. The power module packaging technology described can be applied to all types of devices. In one example, a packaged semiconductor power module includes a first substrate, a second substrate, a sintered-silver semiconductor die pillar, the pillar being positioned between the first substrate and the second substrate, a first terminal on a first side of the power module and electrically coupled to the first substrate, and a second terminal on a second side of the power module and electrically coupled to the second substrate.

In other aspects, the power module can also include an enclosure made of Ultem or polyetherimide, and an insulating encapsulant between the semiconductor die pillar and the enclosure. At least one of the first substrate or the second substrate can include an insulated metal substrate (IMS). The IMS substrate can include a layer of ceramic or polymer between two layers of copper. In one example, the layer of ceramic or polymer is less than or equal to 1 mm in thickness.

In other aspects, the pillar can include a plurality of sintered-silver semiconductor die pillars, and the pillars being positioned between the first substrate and the second substrate. At least one of the plurality of sintered-silver semiconductor die pillars includes a semiconductor device die positioned in a stack between two metal spacers in one example, with sintered-silver interconnections between the semiconductor device die and the two metal spacers. At least one of the plurality of sintered-silver semiconductor die pillars includes a semiconductor device die positioned in a stack next to a metal spacer in another example, with a sintered-silver interconnection between the semiconductor device die and the metal spacer.

The plurality of sintered-silver semiconductor die pillars can be a 2×2 array of pillars in one example. The plurality of sintered-silver semiconductor die pillars can be a 4×4 array of pillars in another example. Additionally, in one case, each of the plurality of sintered-silver semiconductor die pillars includes a diode, and the diodes are arranged in a parallel configuration in the power module. In another case, each of the plurality of sintered-silver semiconductor die pillars includes a diode, and the diodes are arranged in a full bridge rectifier configuration in the power module.

In other aspects, the first substrate includes an intermediate layer, a first metal layer on one side of the intermediate layer, and a second metal layer on another side of the intermediate layer, and the intermediate layer includes an insulating layer of alumina less than or equal to 1 mm in thickness. In other aspects, the power module also includes a composite coating. The composite coating is coated along at least a length of a peripheral edge of the first metal layer at an interface between the peripheral edge and the intermediate layer. In another example, the composite coating is coated along at least a length of peripheral edges of the first inner metal layer and the second inner metal layer of the first substrate, and the composite coating is coated along at least a length of peripheral edges of the first inner metal layer and the second inner metal layer of the second substrate.

In other aspects, the first substrate includes a first intermediate layer, a first inner metal layer on one side of the first intermediate layer, a second inner metal layer on the one side of the first intermediate layer, and an outer metal layer on another side of the first intermediate layer. The second substrate includes a second intermediate layer, a first inner metal layer on one side of the second intermediate layer, a second inner metal layer on the one side of the second intermediate layer, and an outer metal layer on another side of the second intermediate layer.

In one case, the first inner metal layer and the second inner metal layer of the first substrate extend side-by-side in a first longitudinal direction, and the first inner metal layer and the second inner metal layer of the second substrate extend side-by-side in a second longitudinal direction perpendicular to the first longitudinal direction.

### BRIEF DESCRIPTION OF THE DRAWINGS

FIG. 1A illustrates an example cross-sectional side view of a semiconductor power module according to various aspects of the embodiments.

FIG. 1B illustrates an example top-down cross-sectional view of the semiconductor power module designated A-A in FIG. 1A according to various aspects of the embodiments.

FIG. 2A illustrates a perspective view of the power module shown in FIG. 1A according to various aspects of the embodiments.

FIG. 2B illustrates a perspective view of the power module shown in FIG. 1A, with the housing and insulating encapsulant omitted from view, according to various aspects of the embodiments.

FIG. 3 illustrates a perspective view of another power module, with the housing and insulating encapsulant omitted from view, according to various aspects of the embodiments.

FIG. 4 illustrates an electrical diagram of the power module shown in FIG. 3 according to various aspects of the embodiments.

FIG. 5 illustrates the use of a coating on a substrate in the power module shown in FIG. 3 according to various aspects of the embodiments.

FIG. 6 illustrates plots of partial discharge inception voltages for an example power module according to various aspects of the embodiments.

FIG. 7 illustrates an example method of assembly according to various aspects of the embodiments.

### DETAILED DESCRIPTION

Today, medium-voltage (e.g., about <6 kV) silicon-based power semiconductor devices packaged in modules are widely used in electric-grid applications, such as power converters in grid substations. The modules are relied upon to perform various conversion and switching functions that direct the flow of electricity. In one packaging technique, devices in press-pack modules are connected through metal-to-metal physical contacts, by applying a mechanical load on the module. Encapsulation of the module is achieved by filling the sealed module with an inert gas. Another common packaging technology includes wire-bond modules, where power semiconductor die are soldered on an insulated-metal substrate, interconnected with aluminum wires, and encapsulated inside a silicone gel. Modules made by these packaging technologies have low power density limited by a maximum heat dissipation of about 100 to 200 W/cm². The packaged modules also generally have high parasitic inductances and poor reliability from wire-bond lift-off, die-attach cracking, and substrate delamination.

Advances in wide-bandgap devices, such as SiC and gallium nitride (GaN) devices, have facilitated the development of higher efficiency and power-density power electronics converters. These efforts have posed significant challenges on power module packaging, as the packaging structures, materials, and processing conditions significantly influence the thermal, electrical, and mechanical performance and reliability of the modules.

Significant progress has been made toward developing the innovative module packaging concepts described herein, which offer multi-chip module packaging technologies for wide-bandgap semiconductors and other devices. The power module packaging technology described herein has the potential to be applied to all types of medium-voltage devices, including silicon (Si), SiC, GaN, gallium oxide (Ga₂O₃), and others.

Unlike sub-kV power modules, the dielectrics in medium voltage power modules, including the ceramic layers in insulated-metal substrates and encapsulants that protect the devices, are under much higher electric field (E-field) intensity. Especially at triple points (TPs), where three different types of materials (e.g., ceramic, metal, and encapsulant materials) meet, the E-field intensity can be many times higher than nominal E-field intensities at other locations. To make matters worse, TPs can also be trap sites for air bubbles in the encapsulant. This combination of high E-field intensity and air bubbles can often induce partial discharge even under relatively low voltages. Repetitive partial discharge events can accelerate the aging of the encapsulant and cause dielectric fatigue breakdown of power modules.

There have been two main strategies for reducing the E-field stress at TPs and other points in power modules. One strategy has been to modify the geometries at TPs. Examples of the first strategy include thickening the insulation layer of the substrate, stacking multiple insulated-metal substrates to form one, etching electrodes into protrusions, and adding air pockets, cavities, or field plates. These techniques have been relatively ineffective, due to field crowding, increasing the junction-to-case thermal resistance, requiring complex fabrication processes, and for other reasons which are undesirable for power module manufacturing.

Another strategy to reduce E-field stress at TPs is to coat the TPs with certain materials. The coating material can be a particle-filled polymer composite, with the polymer matrix being one of the common polymers, such as polyethylene, epoxy, polyimide, or silicone. Depending on the types of inorganic particles, the composite can have either a high dielectric permittivity for capacitive field-grading or a high electrical conductivity for resistive field-grading. Capacitive field-grading materials normally have high viscosity and require high filler loading to be effective, which makes it easy to trap air bubbles at TPs. Another problem with capacitive field-grading materials is that they function best under alternating current (AC) excitations. Effectiveness under pulse width modulation (PWM) excitations is questionable.

Resistive field-grading materials, which are often referred to as a semiconducting materials, have electrical conductivity between that of an insulator and that of a metal. This type of composite usually exhibits a nonlinear conductivity behavior (i.e., its electrical conductivity increases nonlinearly with applied electric field). By theoretical analysis and finite-element simulation, some research has shown that coating a nonlinear resistive material at TPs can be highly effective for reducing the field stress under direct current (DC), AC, and PWM excitations.

As described below, the concepts described herein include the use of insulated metal substrates (IMS), such as direct bonded copper (DBC) substrates, for packaging double-side cooled medium voltage power modules, and the concepts can be extended to other applications. Because the coatings described herein have been shown to increase the partial discharge inception voltage (PDIV) by about two times, substrates with half of the normally required ceramic thickness can be used for constructing the power modules. This reduces the junction-to-substrate thermal resistance significantly.

One of the key issues for power modules is managing the trade-off between heat dissipation and insulation. According to one example embodiment, a 10-kV full-wave diode rectifier power module incorporates double-sided cooling, wirebond-less interconnections, and thin alumina direct-bond copper substrates to improve thermal performance while maintaining good insulation. For improved performance against electric field breakdown, the TPs on the substrates are also coated by a resistive polymer-nanoparticle composite, to reduce electric field concentrations. In testing, the coating increased the partial discharge inception voltage of the substrate with 0.5-mm thick alumina to 17.8 kV, which presents a significant improvement over that of the substrate without the coating. Electrical and thermal simulations of the module showed a low power loop inductance and a low junction-to-case thermal resistance for the power module.

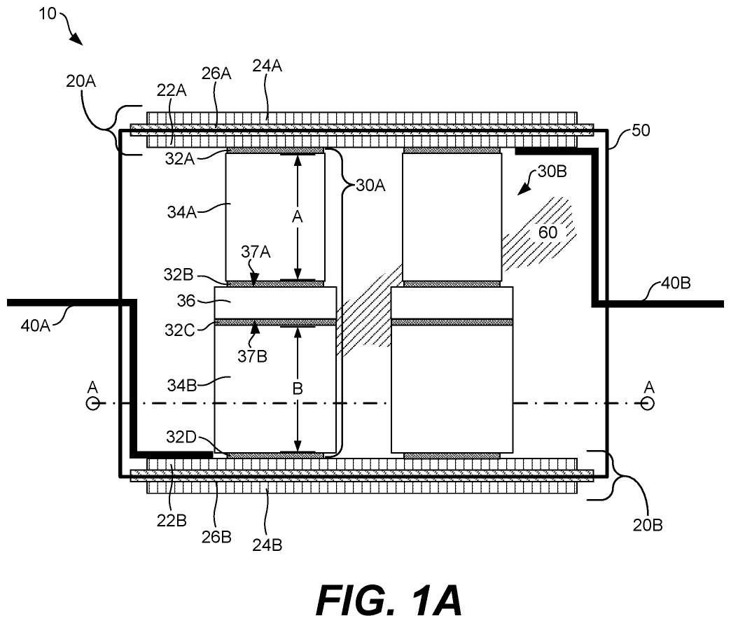

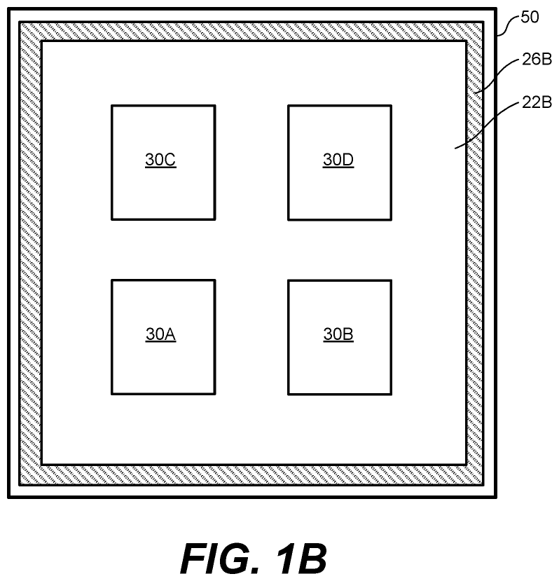

FIG. 1A illustrates an example cross-sectional side view of a semiconductor power module 10 (“power module 10”) according to various aspects of the embodiments. FIG. 1B illustrates the cross-sectional view of the power module 10 designated A-A in FIG. 1A. The power module 10 is illustrated as a representative example in FIGS. 1A and 1B. The power module 10 is not drawn to any particular scale in FIGS. 1A and 1B, and the relative sizes of the individual parts, pieces, or components can vary as compared to that shown. FIGS. 1A and 1B are also not drawn exhaustively, meaning that the power module 10 can include other parts, pieces, or components that are not shown in FIGS. 1A and 1B. Additionally, one or more of the parts, pieces, or components shown in FIGS. 1A and 1B can be omitted in some cases.

The power module 10 is a high power, double-side cooled diode module. A number of important packaging concepts are incorporated in the power module 10 shown in FIGS. 1A and 1B, as described herein. The power module 10 is a multi-chip power module, designed with sintered-silver device interconnections and double-side cooling. Multiple power chips, for high-current handling capability, are laid out in a two-dimensional matrix and chemically bonded between two thermally conductive insulated-metal substrates by an innovative interconnect technology called low-temperature silver sintering. This bonding technology significantly simplifies the manufacturing process.

The power module 10 is a packaged semiconductor module suitable for use in electric power grid applications, such as electric power converters and switching functions in grid sub-stations. The power module 10 is not limited to those applications, however, it can be used in applications other than electric power grid applications. Referring among FIGS. 1A and 1B, the power module 10 includes a first substrate 20A, a second substrate 20B, a number of semiconductor die pillars 30A-30D (collectively “pillars 30”), a first terminal 40A on a first side of the power module 10, a second terminal 40B on a second side of the power module 10, a housing 50, and an insulating encapsulant 60. The first terminal 40A and the insulating encapsulant 60 are omitted from view in FIG. 1B, for simplicity.

The substrate 20A includes a first metal layer 22A, a second metal layer 24A, and an intermediate layer 26A. The intermediate layer 26A is positioned between the first metal layer 22A and the second metal layer 24A, and the metal layers 22A and 24A are bonded to the intermediate layer 26A in the substrate 20A. The first metal layer 22A and the second metal layer 24A can each be embodied as a layer of metal, such as copper, aluminum, or another metal with a high thermal conductivity suitable for conducting heat. The intermediate layer 26A can be an insulating layer, such as a layer of aluminum oxide, alumina, aluminum nitride, or another ceramic, although other materials can be relied upon. The material used for the intermediate layer 26A should preferably be an insulator that exhibits relatively high thermal conductivity. Thus, the first metal layer 22A is electrically isolated from the second metal layer 24A, although heat conducts from the first metal layer 22A, through the intermediate layer 26A, to the second metal layer 24A. In the power module 10, the first metal layer 22A is generally encapsulated within the housing 50, and the second metal layer 24A is generally exposed outside the housing 50. In one example, the first substrate 20A can be embodied as an IMS or DBC substrate.

Similar to the substrate 20A, the substrate 20B includes a first metal layer 22B, a second metal layer 24B, and an intermediate layer 26B. In the power module 10, the first metal layer 22B is generally encapsulated within the housing 50, and the second metal layer 24B is generally exposed outside the housing 50. The materials and arrangement of the layers in the substrate 20B can be the same as that of or similar to the substrate 20A. However, the substrates 20A and 20B can be formed from different materials as compared to each other in some cases.

The semiconductor die pillar 30A (“pillar 30A”) includes a number of interconnections 32A-32D (collectively “interconnections 32”), metal spacers 34A and 34B, and a semiconductor device die 36. In the example shown, the semiconductor device die 36 is positioned between the two metal spacers 34A and 34B in the pillar 30A, with the interconnections 32B and 32C positioned between and electrically coupling the metal spacers 34A and 34B to opposite sides of the semiconductor device die 36. This configuration facilitates the transfer of heat from both sides of the semiconductor device die 36, and the advantages of this arrangement are described in further detail below.

The metal spacers 34A and 34B can be embodied as copper, aluminum, molybdenum, or another metal, in the form of a square or rectangular (e.g., parallelepiped), cylindrical, or tubular spacer or plug, among other shapes. The metal spacers 34A and 34B are shown as rectangular parallelepiped spacers in FIGS. 1A and 1B, and other examples are described below. The metal spacers 34A and 34B are approximately (i.e., to within manufacturing tolerances) the same size as each other in the example shown in FIG. 1A. For example, the height “A” of the metal spacer 34A can be the same as the height “B” of the metal spacer 34B. In other examples, the height “A” can be longer and the height “B” can be shorter, or vice versa, in the pillar 30A.

Each of the pillars 30B-30D is similar to the pillar 30A in the power module 10. However, the pillars 30A-30D can vary as compared to each other in some cases. For example, the relative sizes and shapes of the metal spacers can vary among the pillars 30A-30D, the relative positions of the semiconductor device dies can vary among the pillars 30A-30D, and certain spacers and interconnects can be omitted from one or more of the pillars 30A-30D, among other variations.

The interconnections 32A-32D can be embodied as sintered-silver interconnects in one example. Sintered-silver interconnects can withstand repeated bonding cycles without melting, and sintered-silver joints can be more reliable than soldered joints. The interconnections 32A-32D can be embodied as a paste of nano-sized silver powder in a binder. The silver powder is dispersed in the binder for printing, spreading, or dispensing. In one example, the NanoTach® X Series nanosilver paste of NBE Technologies, LLC, of Blacksburg, VA, USA, can be relied upon for the interconnections 32A-32D, although similar silver sintering die-attach methods can be used. The NanoTach® X Series nanosilver paste can be sintered at a relatively hot temperature of 260° C., which is suitable for the manufacture of the power module 10.

In the power module 10, the sintered-silver interconnections in the semiconductor die pillars 30A-30D can be achieved at temperatures less than about 250° C. The interconnections are capable of allowing the diode devices to work reliably at over 700° C., and the interconnections have at least five times better thermal and electrical conductivities than soldered joints. In testing, the double-sided cooling provided more effective heat extraction capability and layout flexibility, with reduced package parasitics.

The semiconductor device die 36 in the pillar 30A can be embodied as a diode device in one example, although the power module 10 can incorporate other types of semiconductor devices, such as transistors, controlled rectifiers, thyristors, and other devices. Similarly, each of the pillars 30B-30D includes a semiconductor device die embodied as a diode in the example shown, but the pillars 30B-30D can include other types of devices. In one example, the semiconductor device die 36 can be embodied as a diode formed from a wide-bandgap material, such as semiconductor material in the group IV family and semiconductor compounds in the group III-V family, including SiC and gallium nitride, among others. Wide-bandgap semiconductor materials can be relied upon to form devices capable of operating at much higher voltages, frequencies, and temperatures than conventional semiconductor materials like silicon. The power module 10 is not limited to the incorporation of only wide-bandgap semiconductor devices, however, because the power module 10 can include semiconductor devices formed from silicon and other materials.

As shown in FIG. 1B, the power module 10 includes a 2×2 array of four pillars 30A-30D. In other examples, the power module 10 can include larger or smaller linear, rectangular, square, circular, or oval arrays of pillars, including 1×1, 1×2, 1×3, 1×4, or a larger linear array of pillars, 2×3, 2×4, 3×4, 4×4, 4×5, 5×5, 4×6, 5×6, 6×6, or other rectangular or square arrays of pillars, and other arrangements. The pillars 30A-30D can be evenly separated from each other, as best shown in FIG. 1B. In one example, the pillars 30A-30D can be evenly separated from each other by a distance of about 1.5-2.5 mm apart, although smaller or larger spacings can be relied upon.

Referring to FIG. 1A, the semiconductor device die 36 is fabricated to include an anode contact side 37A and a cathode contact side 37B, although it should be appreciated that the anode and cathode contacts can be reversed as compared to the example shown. The semiconductor device dies in the other pillars 30B-30D also include anodes and cathodes similar to the semiconductor device die 36, and all the anodes and all the cathodes are electrically coupled in parallel with each other in the power module 10. Thus, the power module 10 effectively operates as a single, high-power two-terminal diode device.

In the pillar 30A, the anode contact side 37A of the semiconductor device die 36 is electrically and thermally coupled to the metal spacer 34A through the interconnection 32B, and the metal spacer 34A is electrically and thermally coupled to the metal layer 22A of the substrate 20A through the interconnection 32A. Likewise, the cathode contact side 37B is electrically and thermally coupled to the metal spacer 34B through the interconnection 32C, and the metal spacer 34B is electrically and thermally coupled to the metal layer 22B of the substrate 20B through the interconnection 32D. The anodes and cathodes, respectively, of the semiconductor device dies in the other pillars 30B-30D are also electrically and thermally coupled to the metal layer 22A and the metal layer 22B in a similar way. In this arrangement, the overall power handling capacity of the power module 10 can be increased or decreased by adding or omitting pillars.

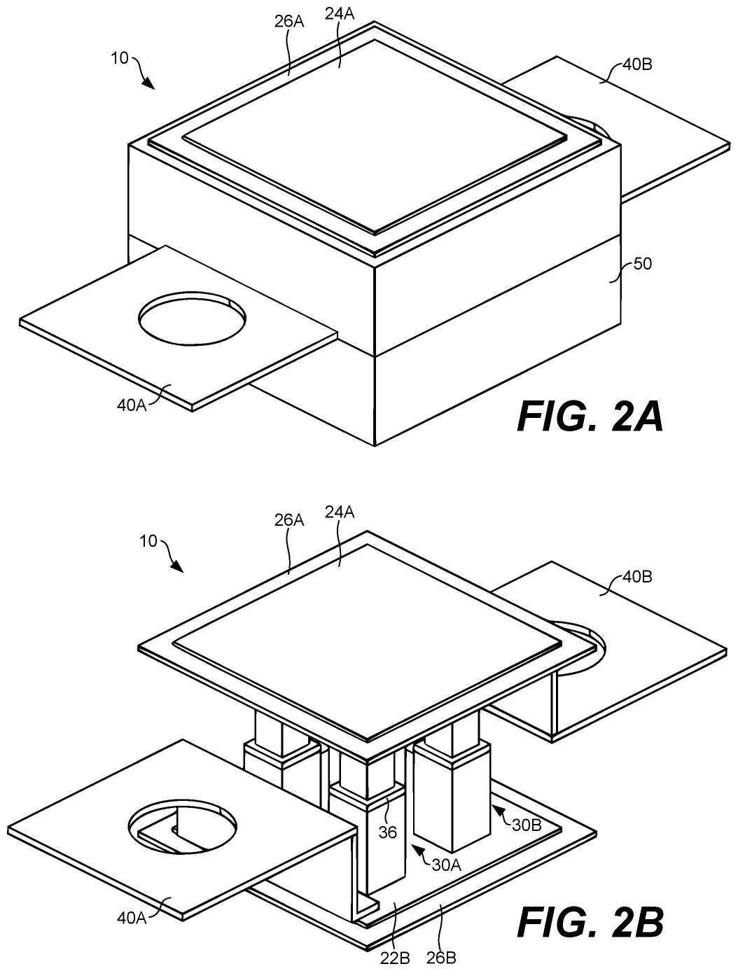

To further illustrate the concepts, FIG. 2A shows a perspective view of the power module 10. FIG. 2B illustrates a perspective view of the power module 10, with the housing 50 and the insulating encapsulant 60 omitted from view. As shown in FIG. 2A, the first terminal 40A can be embodied as a metal (e.g., copper or another conductor) terminal or flange for electrical contact with the power module 10. The first terminal 40A is electrically coupled with the metal layer 22B of the substrate 20A, and the first terminal 40A exits the housing 50 at one side of the power module 10. The second terminal 40B can also be embodied as a metal terminal or flange for electrical contact with the power module 10. The second terminal 40B is electrically coupled with the metal layer 22B of the substrate 20B (see FIG. 1A), and the second terminal 40B exits the housing 50 at another side of the power module 10. With the electrical couplings of the pillars 30A-30D to the metal layers 22A and 22B (see FIG. 1A), the first terminal 40A is an anode terminal of the power module 10, and the second terminal 40B is a cathode terminal of the power module 10.

The housing 50 can be embodied as an enclosure made of a molding compound, such as Ultem or polyetherimide (PEI), as examples, although other materials can be relied upon. As shown in FIG. 1A, the housing 50 is also filled with the insulating encapsulant 60. The insulating encapsulant 60 can be embodied as a silicone gel to encapsulate the pillars 30A-30D, although other materials can be relied upon. PEI is a good electrical insulator with a high continuous working temperature of 171ºC and a high heat deflection temperature of 216° C. Silicone gels are also good electrical insulators and have good flow characteristics that, before curing, can fill narrow gaps inside the power module 10. This is important to prevent trapped air pockets in the encapsulant, which are prone to partial discharge in some cases.

The compact design and selection of materials for the power module 10 result in low junction-to-case thermal resistance as well as low thermo-mechanical stresses caused by mismatched coefficients of thermal expansion. The package design is also flexible for the addition of insulation barriers on the outside of the enclosure to satisfy the clearance and creepage requirements.

In other embodiments, the vertical locations of the semiconductor die can be repositioned as compared to that in the power module 10. For example, the semiconductor die can be repositioned to have one side at or on a metal surface of a DBC substrate for efficient heat extraction without significantly increasing electric-field concentration. A large alumina DBC substrate can also be used to avoid having tight corners that are prone to trapping air bubbles in the encapsulant causing partial discharge and premature dielectric failure.

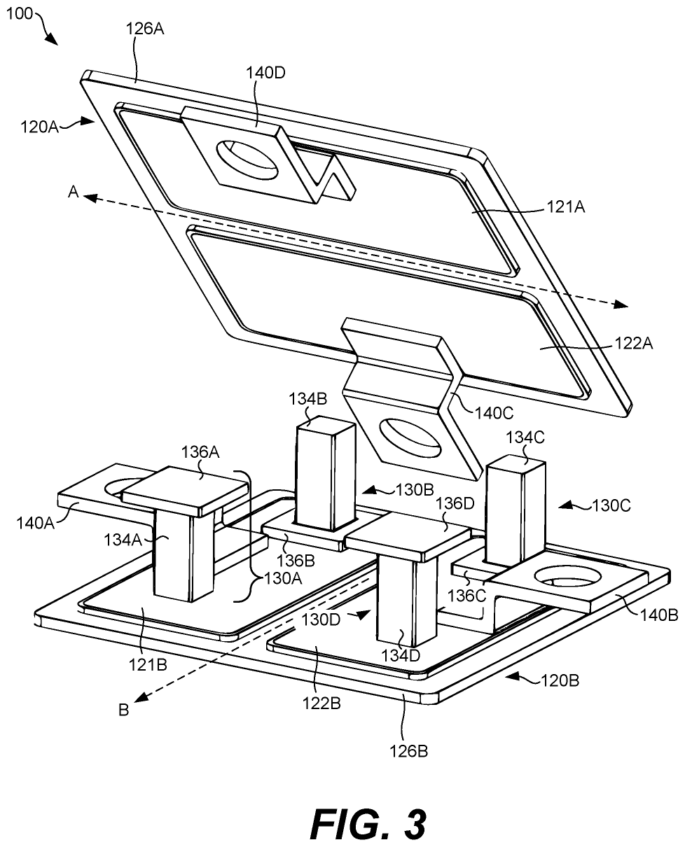

FIG. 3 illustrates a perspective view of another power module 100, with the housing and insulating encapsulant of the module omitted from view, according to various aspects of the embodiments. The power module 100 is illustrated as a representative example in FIG. 3. The power module 100 is not drawn to any particular scale in FIG. 3, and the relative sizes of the individual parts, pieces, or components can vary as compared to that shown. FIG. 3 is also not drawn exhaustively, meaning that the power module 100 can include other parts, pieces, or components that are not shown. Additionally, one or more of the parts, pieces, or components shown in FIG. 3 can be omitted in some cases.

The power module 100 is a high power, double-side cooled diode module. As compared to the power module 10, the diodes in the power module 100 are arranged in a full bridge configuration. A number of important packaging concepts are incorporated in the power module 100. The power module 100 is a multi-chip power module, designed with sintered-silver device interconnections and double-side cooling. Multiple power chips are laid out in a two-dimensional matrix and chemically bonded between two thermally conductive insulated-metal substrates by an innovative interconnect technology called low-temperature silver sintering. This bonding technology significantly simplifies the manufacturing process. The power module 100 is a packaged semiconductor module suitable for use in electric power grid applications, among other applications.

Referring to FIG. 3, the power module 100 includes a first substrate 120A, a second substrate 120B, a number of semiconductor die pillars 130A-130D (collectively “pillars 130”), a first terminal 140A on a first side of the power module 100, a second terminal 140B on a second side of the power module 100, a third terminal 140C on a third side of the power module 100, and a fourth terminal 140D (collectively “terminals 140”) on a fourth side of the power module 100, an insulating encapsulant, and a housing. The first substrate 120A is illustrated in a lifted position in FIG. 3, so that the pillars 130 can be seen, and the insulating encapsulant and housing of the power module 100 are omitted from view for simplicity.

When fully assembled with the insulating encapsulant and housing, the power module 100 appears similar to the power module 10 shown in FIG. 2A, although the terminals 140 are positioned around all four sides of the power module 100. Also, the power module 100 can be relatively thinner, as measured between the outer surfaces of the substrates 120A and 120B, as compared to the same measurement taken between the outer surfaces of the substrates 20A and 20B in the power module 10. The power module 100 is thinner than the power module 10 because the pillars 130 include only one and not two spacers, as compared to the pillars 30 in the power module 10.

The first substrate 120A includes a first inner metal layer 121A, a second inner metal layer 122A, an intermediate layer 126A, and an outer metal layer (not shown). The intermediate layer 126A is positioned between the inner metal layers 121A and 122A and the outer metal layer. The metal layers of the substrate 120A are bonded to the intermediate layer 126A of the substrate 120A. The inner metal layers 121A and 122A extend, side-by-side, in the first longitudinal direction “A”. The outer metal layer of the substrate 120A can be embodied as a single, larger metal layer, similar to the second metal layer 24A of the substrate 20A.

The inner metal layers 121A and 122A and the outer metal layer of the first substrate 120A can each be embodied as a layer of metal, such as copper, aluminum, or another metal with a high thermal conductivity suitable for conducting heat. The intermediate layer 126A can be an insulating layer, such as a layer of ceramic, aluminum oxide, alumina, aluminum nitride, or another ceramic, although other materials, including polymers, can be relied upon. The material used for the intermediate layer 126A should preferably be an insulator that exhibits relatively high thermal conductivity. Thus, the inner metal layers 121A and 122A are electrically isolated from the outer metal layer, although heat conducts from the inner metal layers 121A and 122A, through the intermediate layer 126A, to the outer metal layer. In the power module 100, the inner metal layers 121A and 122A are generally encapsulated within the housing of the power module 100, and the outer metal layer is generally exposed outside of the housing. In one example, the first substrate 120A can be embodied as a DBC substrate.

The second substrate 120B includes a first inner metal layer 121B, a second inner metal layer 122B, an intermediate layer 126B, and an outer metal layer (not shown). The intermediate layer 126B is positioned between the inner metal layers 121B and 122B and the outer metal layer. The metal layers of the substrate 120B are bonded to the intermediate layer 126B of the substrate 120B. The inner metal layers 121B and 122B extend, side-by-side, in the second longitudinal direction “B,” which is perpendicular to the first longitudinal direction “A.” The outer metal layer of the substrate 120B can be embodied as a single, larger metal layer, similar to the second metal layer 24A of the substrate 20A.

The inner metal layers 121B and 122B and the outer metal layer of the second substrate 120B can each be embodied as a layer of metal, such as copper, aluminum, or another metal with a high thermal conductivity suitable for conducting heat. The intermediate layer 126B can be an insulating layer, such as a layer of ceramic, aluminum oxide, alumina, aluminum nitride, or another ceramic, although other materials, including polymers, can be relied upon. The material used for the intermediate layer 126B should preferably be an insulator that exhibits relatively high thermal conductivity. Thus, the inner metal layers 121B and 122B are electrically isolated from the outer metal layer, although heat conducts from the inner metal layers 121B and 122B, through the intermediate layer 126B, to the outer metal layer. In the power module 100, the inner metal layers 121B and 122B are generally encapsulated within the housing of the power module 100, and the outer metal layer is generally exposed outside of the housing. In one example, the second substrate 120B can be embodied as a DBC substrate.

The semiconductor die pillar 130A (“pillar 130A”) includes a metal spacer 134A and a semiconductor device die 136A. Although obscured from view in FIG. 3, the power module 100 includes a silver-sintered interconnection between one end of the metal spacer 134A and the anode contact at the bottom surface of the semiconductor device die 136A. The power module 100 also includes a silver-sintered interconnection between another end of the metal spacer 134A and the first inner metal layer 121B of the substrate 120B. Additionally, a silver-sintered interconnection exists between the cathode contact at the top surface of the semiconductor device die 136A and the first inner metal layer 121A of the substrate 120A.

The semiconductor die pillar 130B (“pillar 130B”) includes a metal spacer 134B and a semiconductor device die 136B. The power module 100 includes a silver-sintered interconnection between the anode contact at the bottom surface of the semiconductor device die 136B and the first inner metal layer 121B of the substrate 120B. The power module 100 also includes a silver-sintered interconnection between the cathode contact at the top surface of the semiconductor device die 136B and one end of the metal spacer 134B. Additionally, the power module 100 also includes a silver-sintered interconnection between the other end of the metal spacer 134B and the second inner metal layer 122A of the substrate 120A.

The semiconductor die pillar 130C (“pillar 130C”) includes a metal spacer 134C and a semiconductor device die 136C. The power module 100 includes a silver-sintered interconnection between the cathode contact at the bottom surface of the semiconductor device die 136C and the second inner metal layer 122B of the substrate 120B. The power module 100 also includes a silver-sintered interconnection between the anode contact at the top surface of the semiconductor device die 136C and one end of the metal spacer 134C. Additionally, the power module 100 also includes a silver-sintered interconnection between the other end of the metal spacer 134C and the second inner metal layer 122A of the substrate 120A.

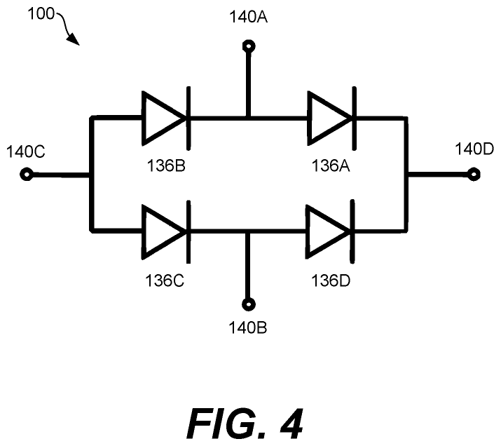

The semiconductor die pillar 130D (“pillar 130D”) includes a metal spacer 134D and a semiconductor device die 136D. The power module 100 includes a silver-sintered interconnection between the anode contact at the top surface of the semiconductor device die 136D and the first inner metal layer 121A of the substrate 120A. The power module 100 also includes a silver-sintered interconnection between the cathode contact at the bottom surface of the semiconductor device die 136D and one end of the metal spacer 134D. Additionally, the power module 100 also includes a silver-sintered interconnection between the other end of the metal spacer 134D and the second inner metal layer 122B of the substrate 120B. FIG. 4 illustrates an electrical diagram of the power module 100 shown in FIG. 3 based on the electrical interconnects described above. As shown in FIG. 4, the power module 100 comprises a full bridge rectifier.

Similar to the power module 10, the interconnections in the pillars 130A-130D of the power module 100 can be embodied as sintered-silver interconnects. Sintered-silver interconnects can withstand repeated bonding cycles without melting, and sintered-silver joints can be more reliable than soldered joints. The interconnections can be embodied as a paste of nano-sized silver powder in a binder, such as the NanoTach® X Series nanosilver paste. A method of assembling the power module 100, the metal spacers, and the sintered-silver interconnects is described below.

In the power module 100, the sintered-silver interconnections in the pillars 130A-130D can be achieved at temperatures less than about 250° ° C. The interconnections are capable of allowing the diode devices to work reliably at over 700° C., and the interconnections have at least five times better thermal and electrical conductivities than soldered joints. In testing, the double-sided cooling provided more effective heat extraction capability and layout flexibility, with reduced package parasitics.

As described above, the semiconductor device die 136A in the pillar 30A is embodied as a diode device, although the power module 100 can incorporate other types of semiconductor devices, such as transistors, controlled rectifiers, thyristors, and other devices. Similarly, each of the semiconductor device die 136B-136D is embodied as a diode in the example, but the pillars 130A-130D can include other types of devices. In one example, the semiconductor device die 136A-136D can be embodied as diodes formed from a wide-bandgap material, such as semiconductor material in the group IV family and semiconductor compounds in the group III-V family, including SiC and gallium nitride, among others. Wide-bandgap semiconductor materials can be relied upon to form devices capable of operating at much higher voltages, frequencies, and temperatures than conventional semiconductor materials like silicon. The power module 100 is not limited to the incorporation of only wide-bandgap semiconductor devices, however, because the power module 100 can include semiconductor devices formed from silicon and other materials.

As shown in FIG. 3, the power module 100 includes a 2×2 array of four pillars 130A-130D. In other examples, the power module 100 can include smaller or larger numbers of pillars, including other configurations of diodes. The pillars 130A-130D can be evenly separated from each other, as shown, or spaced in other configurations.

The housing of the power module 100 (not shown) can be embodied as an enclosure made of Ultem or polyetherimide (PEI), as examples, although other materials can be relied upon. The housing can also be filled with an insulating encapsulant, such as a silicone gel to encapsulate the pillars 130A-130D, although other materials can be relied upon. PEI is a good electrical insulator with a high continuous working temperature and a high heat deflection temperature. Silicone gels are also good electrical insulators and have good flow characteristics that, before curing, can fill narrow gaps inside the power module 100. This is important to prevent trapped air pockets in the encapsulant, which are prone to partial discharge in some cases.

In power modules, DBC substrates with thicker ceramic layers (i.e., the internal insulating layers) may be preferred to ensure electrical insulation. However, because the thermal conductivity of a typical ceramic material, like alumina, is much lower than that of copper, a thicker alumina DBC substrate can lead to higher thermal resistance. To explore a good balance between electrical insulation and thermal conductivity, thermal simulations were conducted to evaluate the effect of different thicknesses of the alumina layer in DBC substrates on the junction temperatures of the semiconductor die. DBC substrates with alumina thicknesses equal to 0.38 mm, 0.5 mm, and 1.0 mm were evaluated. Except for the alumina thickness and power loss per chip, all other parameters for the simulations were kept the same. The DBC substrate thermal resistances and the junction-to-case thermal resistances were respectively extracted from simulations.

At a diode power loss of 60 W, the device in the package using 0.5 mm alumina DBC substrates was 9.5° C. cooler than that packaged using 1.0 mm alumina DBC. This is because the thinner substrate had 43.6% lower thermal resistance, which lowered the junction-to-case thermal resistance by 28.4%. It was found that the DBC substrate thermal resistance contributes more than 65% to the junction-to-case thermal resistance. This is because the thermal conductivity of alumina is about 15 times lower than that of copper and silicon carbide. Thus, having the ability to use DBC substrates with thinner alumina layers offers a thermal benefit.

The insulating layers of DBC substrates cannot be too thin, however, because dielectric breakdown can lead to failure of power modules. Dielectric breakdown tests were also performed on the DBC substrates. A typical insulator in DBC substrates is a ceramic of aluminum oxide or aluminum nitride. Both ceramics have a similar dielectric breakdown strength. Aluminum nitride is more expensive but has a much higher thermal conductivity than aluminum oxide. For making the 5-kV module, an aluminum oxide DBC substrate was selected.

In a typical breakdown voltage test, the DBC substrate was pressed between two brass electrodes and immersed in a transformer oil for testing. A 60-Hz sinusoidal voltage source was used and followed with an insulation test procedure recommended by the International Electrotechnical Commission (IEC). The DBC substrate with a 0.5 mm ceramic insulator thickness broke down at 15 kV±1 kV during testing, without showing any signs of partial discharge. The 0.5 mm ceramic insulator substrate has a sufficiently high breakdown strength for the 5-kV module, but it cannot suitably be used to package a 20-kV module, for which the substrate has to survive a 41-kV bias without breakdown according to some standards.

In other testing, dielectric breakdown strengths of alumina DBC substrates with three different ceramic thicknesses, including 0.375 mm, 0.5 mm, and 1.0 mm, were evaluated. The recess between copper metallization and alumina on the outer surfaces of the substrates was 1.59 mm for all three. For each alumina thickness, six substrates were tested. All the substrates survived a peak voltage of 11 kV (targeting value for the 5 kV module) from a sinusoidal 60 Hz source, without breakdown or partial discharge. According to the results, with increasing thickness, the breakdown voltage also increased, but not linearly with thickness. By calculating the breakdown average electric field, it was found that the thinner alumina withstood a higher average electric field. Two possible explanations include (1) the thicker alumina may have more defects introduced by the fabrication process, leading to a lower breakdown average field, and (2) the electric field inside thicker alumina is more non-uniform with higher field concentration, which also might result in a lower breakdown average field.

By using a differential input, namely, setting the voltages of the two module input terminals at +Um/2 and −Um/2, the ceramic of the DBC substrate would only need to sustain half of the maximum voltage. This means that the 1.0 mm thick alumina DBC substrate would satisfy the requirement for use in the 20 kV module. According to the IEC standard, the required insulation breakdown voltage for the 20 kV module needs to be 41/2=21.5 kV, which is less than the 27.5 kV breakdown voltage measured on the 1 mm thick alumina DBC. This result suggests the use of an alumina DBC substrate with the ceramic thickness of at least 1 mm for making 20 kV power modules.

To use DBC substrates with thinner insulating layers for thermal benefits while also conforming to standards for partial discharge and improved reliability, a coating can be relied upon in the power modules 10 and 100. In one embodiment, the coating material can be a resistive field-grading material having electrical conductivity between that of an insulator and a metal. This type of composite material usually exhibits a nonlinear conductivity behavior (i.e., its electrical conductivity increases nonlinearly with applied electric field).

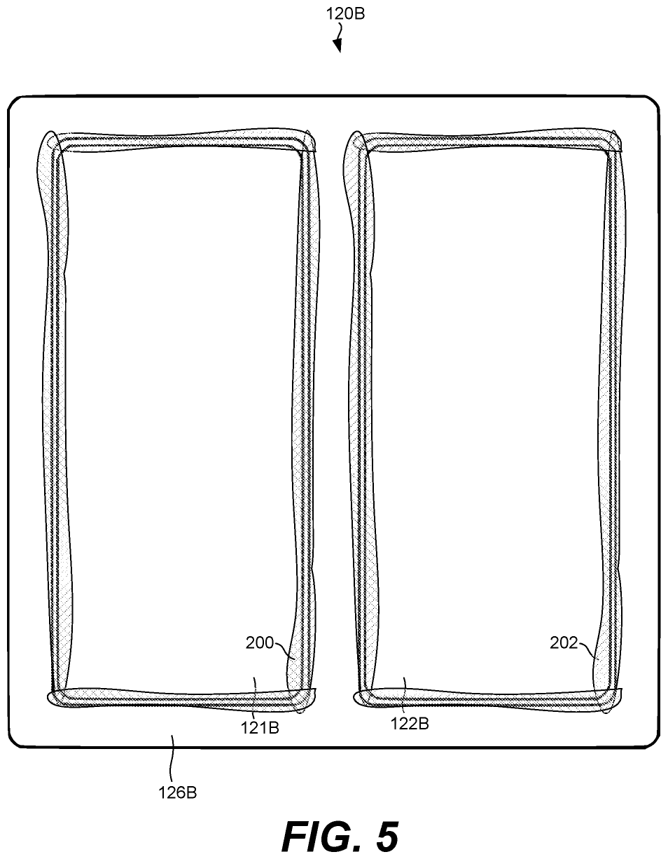

FIG. 5 illustrates the use of a coating on the substrate 120B in the power module 100 according to various aspects of the embodiments. The in-trench TPs on DBC substrates have been identified as weak regions for partial discharge and dielectric breakdown. By coating the TPs, the electric field stress can be reduced by about 50%, thus improving the partial discharge inception voltage (PDIV) significantly. As shown in FIG. 5, the coating 200 is applied along the peripheral edge of the first inner metal layer 121B where it meets the top surface of the intermediate layer 126B. Similarly, the coating 202 is applied along the peripheral edge of the second inner metal layer 122B where it meets the top surface of the intermediate layer 126B.

In one example, a coating known under the trade name nanoEshield™ from NBE Technologies, LLC, of Blacksburg, VA, USA, was used for the coatings 200 and 202, although other coatings can be relied upon. The nanoEshield™ coating was applied by a small paint brush along the peripheral edges of the inner metal layers 121B and 122B of the second substrate 120B, as shown in FIG. 5. The coating was also applied along the peripheral edges of the inner metal layers 121A and 122A of the first substrate 120A. The coating was cured at about 180° C. for about 30 minutes. The coated substrates 120A and 120B were then encapsulated in a silicone gel (Wacker SilGel® 612) for partial discharge testing. Substrates without the coating were also prepared and tested for partial discharge.

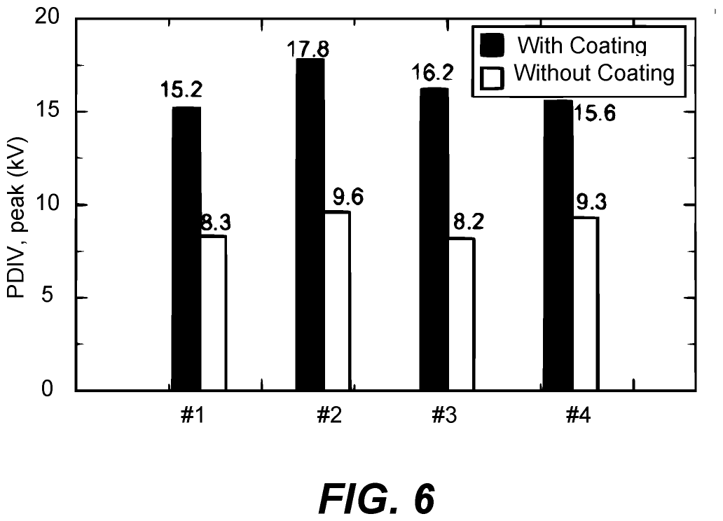

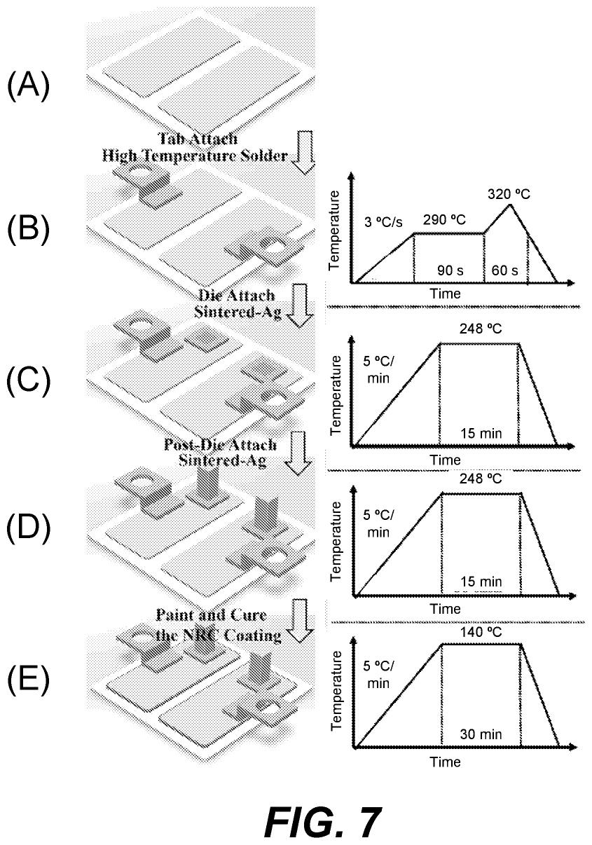

Partial discharge tests on the substrates were run under 60 Hz AC voltage excitation to determine their PDIVs. FIG. 6 illustrates plots of partial discharge inception voltages for example power modules with and without the coating. The lowest PDIV of the uncoated substrate was 8.2 kV, while all the coated substrates had a PDIV higher than 15 kV.

PDIVs of “mark-up” modules without devices were also tested. A “mark-up” module that consisted of a PEI housing, copper terminal tabs, silicone gel encapsulation, and an uncoated 0.5 mm alumina DBC substrate was tested. The first reading of its PDIV was at 8.7 kV, which is within the PDIV range found on the uncoated substrates. However, the second measurement was 6.2 kV, which is 2.5 kV lower than the first. This considerable degradation of the silicone gel insulation in this test is why a significant PDIV margin is necessary to ensure the reliability of power modules. Upon further increase of the peak voltage to 9.5 kV, dielectric breakdown occurred in the substrate trench during the test. The experiment demonstrated that the 0.5 mm alumina DBC substrates without the coating would not be as suitable to package 10 kV devices. Another “mark-up” module using coated 0.5 mm alumina DBC substrates was fabricated. It withstood 14 kV AC peak voltage for 5 minutes without any partial discharge event higher than 1 pC, demonstrating that the 0.5 mm alumina DBC substrates with the coating would be more suitable to package 10 kV devices.

FIG. 7 illustrates an example method of assembly according to various aspects of the embodiments. The method of assembly can be relied upon, in part, to manufacture or assemble the power module 100, and it can be extended for use to assemble the power module 10. The module package shown in FIG. 7 includes two halves, each with two diodes mounted on one DBC substrate. The module assembly can proceed by processing the halves separately, followed by connecting the two to form the full power module.

FIG. 7 shows the fabrication flow for making one half of the power module 100, with the temperature profiles at the side of each step. The process includes providing a substrate at step (A). The substrate can be one of the DBC substrates described herein. The process includes soldering machined copper tabs on the DBC substrate using a high-temperature solder at step (B). The process also includes silver-sintering diodes on the substrate using silver or nanosilver paste as described herein at step (C). The temperature profile, including a ramp rate, is shown in FIG. 7. Pressure can be applied during the silver-sintering process once the peak temperature is reached, such as at 245° C., when pressure can be applied for a period of 15 minutes as shown. The process also includes silver-sintering metal spacers on the diode anodes at step (D). Before the two half-packages were sintered together, the process also includes painting the coating along the copper edges of the DBC substrates and curing the coating at about 180° C. for about 30 minutes at step (E). After the coating is cured, the process includes connecting the two half-packages together by silver-sintering. The process also includes securing the two half-packages together by an underfill material. The empty space in the package was also filled with silicone gel. To avoid trapping air bubbles inside the module, the silicone gel was degassed at about 1 kPa for 30 minutes, followed by curing at room temperature for 24 hours. The housing can also be provided around the module in some cases.

Although embodiments have been described herein in detail, the descriptions are by way of example. In other words, the embodiments of the frame described herein are not limited to frame structures for aircraft, however, and may be relied upon as frame structures for both airborne and ground-based crafts, vehicles, etc. The features of the embodiments described herein are representative and, in alternative embodiments, certain features and elements may be added or omitted. Additionally, modifications to aspects of the embodiments described herein may be made by those skilled in the art without departing from the spirit and scope of the present invention defined in the following claims, the scope of which are to be accorded the broadest interpretation so as to encompass modifications and equivalent structures.

1. A packaged semiconductor power module, comprising:
a first substrate;
a second substrate;
a sintered-silver semiconductor die pillar, the pillar being positioned between the first substrate and the second substrate;
a first terminal on a first side of the power module and electrically coupled to the first substrate; and
a second terminal on a second side of the power module and electrically coupled to the second substrate.

2. The power module of claim 1, further comprising:
an enclosure made of a molding compound; and
an insulating encapsulant between the semiconductor die pillar and the enclosure.

3. The power module of claim 1, wherein at least one of the first substrate or the second substrate comprises an insulated metal substrate (IMS).

4. The power module of claim 3, wherein:
the IMS comprises a layer of ceramic or polymer between two layers of copper; and
the layer of ceramic or polymer is less than or equal to 1 mm in thickness.

5. The power module of claim 1, wherein the pillar comprises a plurality of sintered-silver semiconductor die pillars, the pillars being positioned between the first substrate and the second substrate.

6. The power module of claim 5, wherein the plurality of sintered-silver semiconductor die pillars comprise a 2×2 array of pillars.

7. The power module of claim 5, wherein the plurality of sintered-silver semiconductor die pillars comprise a 4×4 array of pillars.

8. The power module of claim 5, wherein:
each of the plurality of sintered-silver semiconductor die pillars comprises a diode; and
the diodes are arranged in a parallel configuration in the power module.

9. The power module of claim 5, wherein:
each of the plurality of sintered-silver semiconductor die pillars comprises a diode; and
the diodes are arranged in a full bridge rectifier configuration in the power module.

10. The power module according to claim 5, wherein at least one of the plurality of sintered-silver semiconductor die pillars comprises a semiconductor device die positioned in a stack between two metal spacers, with sintered-silver interconnections between the semiconductor device die and the two metal spacers.

11. The power module according to claim 5, wherein at least one of the plurality of sintered-silver semiconductor die pillars comprises a semiconductor device die positioned in a stack next to a metal spacer, with a sintered-silver interconnection between the semiconductor device die and the metal spacer.

12. The power module of claim 1, wherein:
the first substrate comprises an intermediate layer, a first metal layer on one side of the intermediate layer, and a second metal layer on another side of the intermediate layer; and
the intermediate layer comprises an insulating layer of ceramic or polymer less than or equal to 1 mm in thickness.

13. The power module of claim 12, further comprising:
a composite coating, the composite coating being coated along at least a length of a peripheral edge of the first metal layer at an interface between the peripheral edge and the intermediate layer.

14. The power module of claim 1, wherein:
the first substrate comprises a first intermediate layer, a first inner metal layer on one side of the first intermediate layer, a second inner metal layer on the one side of the first intermediate layer, and an outer metal layer on another side of the first intermediate layer; and
the second substrate comprises a second intermediate layer, a first inner metal layer on one side of the second intermediate layer, a second inner metal layer on the one side of the second intermediate layer, and an outer metal layer on another side of the second intermediate layer.

15. The power module of claim 14, wherein:
the first inner metal layer and the second inner metal layer of the first substrate extend side-by-side in a first longitudinal direction; and
the first inner metal layer and the second inner metal layer of the second substrate extend side-by-side in a second longitudinal direction perpendicular to the first longitudinal direction.

16. The power module of claim 14, further comprising a composite coating, wherein:
the composite coating is coated along at least a length of peripheral edges of the first inner metal layer and the second inner metal layer of the first substrate; and
the composite coating is coated along at least a length of peripheral edges of the first inner metal layer and the second inner metal layer of the second substrate.

17. A packaged semiconductor power module, comprising:
a first substrate;
a second substrate;
a plurality of sintered-silver semiconductor die pillars positioned between the first substrate and the second substrate;
a first terminal on a first side of the power module and electrically coupled to the first substrate; and
a second terminal on a second side of the power module and electrically coupled to the second substrate, wherein
at least one of the plurality of sintered-silver semiconductor die pillars comprises a semiconductor device die positioned in a stack next to a metal spacer, with a sintered-silver interconnection between the semiconductor device die and the metal spacer.

18. The power module of claim 17, wherein:
the first substrate comprises an intermediate layer, a first metal layer on one side of the intermediate layer, and a second metal layer on another side of the intermediate layer; and
the intermediate layer comprises an insulating layer of ceramic or polymer less than or equal to 1 mm in thickness.

19. The power module of claim 18, further comprising:
a composite coating, the composite coating being coated along at least a length of a peripheral edge of the first metal layer at an interface between the peripheral edge and the intermediate layer.

20. The power module of claim 17, wherein the plurality of sintered-silver semiconductor die pillars comprise a 2×2 array of pillars.
